(19) United States
(12) Patent Application Publication
(10) Pub. No.: US 2015/0016116 A1
(43) Pub. Date: Jan. 15, 2015

(54) FLEXIBLE LED LIGHT BAR AND MANUFACTURING METHOD THEREOF

(71) Applicant: XIAMEN CHANGELIGHT CO., LTD., XIAMEN (CN)

(72) Inventors: ZUNXIANG HUANG, XIAMEN (CN); YUANMING LI, XIAMEN (CN)

(73) Assignee: XIAMEN CHANGELIGHT CO., LTD., XIAMEN (CN)

(21) Appl. No.: 14/165,600

(22) Filed: Jan. 28, 2014

(30) Foreign Application Priority Data
Jul. 15, 2013 (CN) 201310295186.3

(51) Int. Cl. F21V 19/00; H05K 3/34; H05K 3/28

(52) U.S. Cl. CPC F21V 19/005; H05K 3/284; H05K 3/341; H05K 2203/04; H05K 2203/1305
USPC 362/296.01; 362/418; 29/841; 29/840

(57) ABSTRACT

The present invention discloses a flexible LED light bar, which includes a flexible circuit board, a light cup, an LED chip, and an LED encapsulation material. The light cup is formed on the flexible circuit board. The LED chip is encapsulated in the light cup and is bonded to the flexible circuit board to form electrical connection therebetween. The present invention also provides a manufacturing method of a flexible LED light bar. The present invention simplifies the manufacturing process of the flexible LED light bar, reducing the manufacturing cost, and also improves product reliability

### (a) TECHNICAL FIELD OF THE INVENTION

The present invention generally relates to a flexible LED light bar and a manufacturing method thereof, and more particularly to a flexible LED light bar in which a light cup is formed on a flexible circuit board and an LED chip is encapsulated in the light cup and bonded to the flexible circuit board with ancillary electronic components being soldered to the flexible circuit board to thereby enable light emission after being energized.

### (b) DESCRIPTION OF THE PRIOR ART

Heretofore, a manufacturing process of a flexible LED light bar is as follows. An encapsulation operation is applied to encapsulate LED chips on an LED frame in order to form individual LED units are being divided. The LED units are then subjected to a manufacturing process to be soldered to a flexible circuit board. FIG. 1 is a schematic view showing a commonly seen structure of a conventional flexible LED light bar, of which a manufacturing process is to first apply an encapsulating operation to form an LED-mounted light unit 20 and then a mounting machine and a reflow machine are used to subject the encapsulated LED-mounted light unit to soldering to a flexible circuit board 30 by means of solder pads 10 so as to make a flexible LED light bar. Such a manufacturing process has high costs for LED encapsulation frame and subsequent soldering operations and this leads to a higher product manufacturing cost. Further, in the operation such a flexible LED light bar, heat of the LED chip is transmitted to the flexible circuit board primarily through pins 40 of the mounted light unit, of which a heat conductive area is relatively small, so that heat cannot be effectively dissipated, leading to relatively severe optic deterioration of the LED chip and relatively poor product reliability.

### SUMMARY OF THE INVENTION

To overcome such a problem, an object of the present invention is to provide a flexible LED (Light-Emitting Diode) light bard and a manufacturing method thereof, which simplify the manufacturing process, reduce the manufacturing cost, and enhance product reliability.

To achieve the above object, the present invention adopts the following technical solution:

A flexible LED light bar comprises a flexible circuit board, a light cup, an LED chip, and an LED encapsulation material. The light cup is formed on the flexible circuit board. The LED chip is encapsulated by the LED encapsulation material in the light cup and bonded to the flexible circuit board. The LED chip is in electrical connection with the flexible circuit board.

The flexible LED light bar further comprises an electronic component. The electronic component is soldered to the flexible circuit board. The electronic component is in electrical connection with the flexible circuit board.

The flexible LED light bar comprises multiple sets of the flexible circuit board, the light cup, the LED chip, and the LED encapsulation material, which are electrically connected to each other through series connection or parallel connection or a combination of series and parallel connections.

The flexible circuit board comprises a circuit board formed through printing and etching. Applying operations of printing and etching to form a circuit board allows for simplification of transfer of a circuit pattern to achieve high repeatability and consistency of the pattern; excellent adhesion between conductive wiring and an insulation substrate and good stability of the circuit;

high precision and being easily integrateable to achieve high density interconnection so as to meet the needs for complicated circuit and control. Further applying the operation of printing and etching to form a circuit board further achieves advantages of excellent heat dissipation, solderability, and reduced manufacturing cost.

The flexible circuit board further comprises a reflective layer formed through electroplating, sputtering, or nano-spray coating.

A manufacturing method of a flexible LED light bar, characterized by comprising the following steps:

(1) providing a flexible circuit board;

(2) forming a light cup on the flexible circuit board; and

(3) using LED encapsulation facility and an LED encapsulation material to encapsulate the LED chip in the light cup and bonded to the flexible circuit board and establishing an electrical connection between the LED chip and the flexible circuit board so as to form an LED light bar.

A pre-step is performed before step (3) and comprises using manufacturing facility to solder an electronic component to the flexible circuit board so that an electrical connection is established between the electronic component and the flexible circuit board.

Step (4) is performed after step (3) and comprises jointing a number of the LED light bars formed in step (3) to each other through series connection, parallel connection or a combination of series and parallel connection.

A pre-step is formed before step (2) and comprising a reflective layer on the flexible circuit board through electroplating, sputtering, or nano-spray coating.

The flexible circuit board comprises a circuit board that is formed through printing or etching.. Applying operations of printing and etching to form a circuit board allows for simplification of transfer of a circuit pattern to achieve high repeatability and consistency of the pattern; excellent adhesion between conductive wiring and an insulation substrate and good stability of the circuit; high precision and being easily integrateable to achieve high density interconnection so as to meet the needs for complicated circuit and control.

By adopting the above solution, the present invention allows an LED chip to be directly encapsulated on a flexible circuit board thereby reducing the manufacturing cost of a flexible LED light bar and achieving excellent repeatability, consistency, and stability of products so as to form a flexible LED light bar that can be of a complicated circuit design and forms various control functions. Further, the present invention allows an LED chip to be directly bonded to a flexible circuit board to establish electrical connection therebetween, whereby when the flexible LED light bar is in operation, the heat generated by the LED chip can be well transmitted out via the flexible circuit board to thereby increase the heat dissipative area, allows the operation temperature of the LED chip to be reduced, reduce optical deterioration of the LED chip, and improve the product reliability.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic view showing a conventional structure.

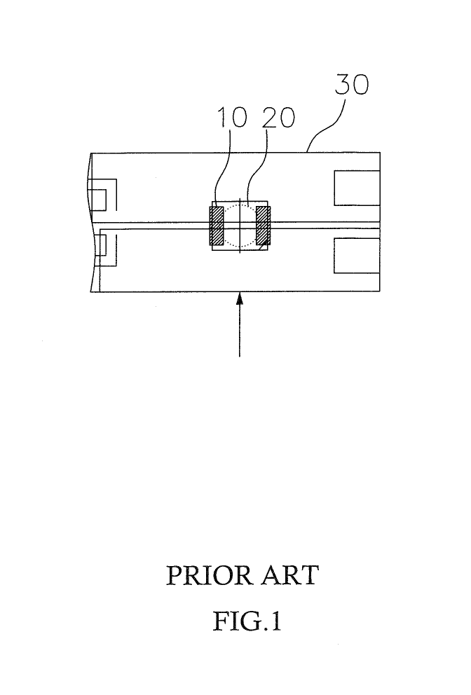

FIG. 2 is a schematic view showing a structure according to the present invention.

FIG. 3 is a flow chart illustrating a manufacturing process of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

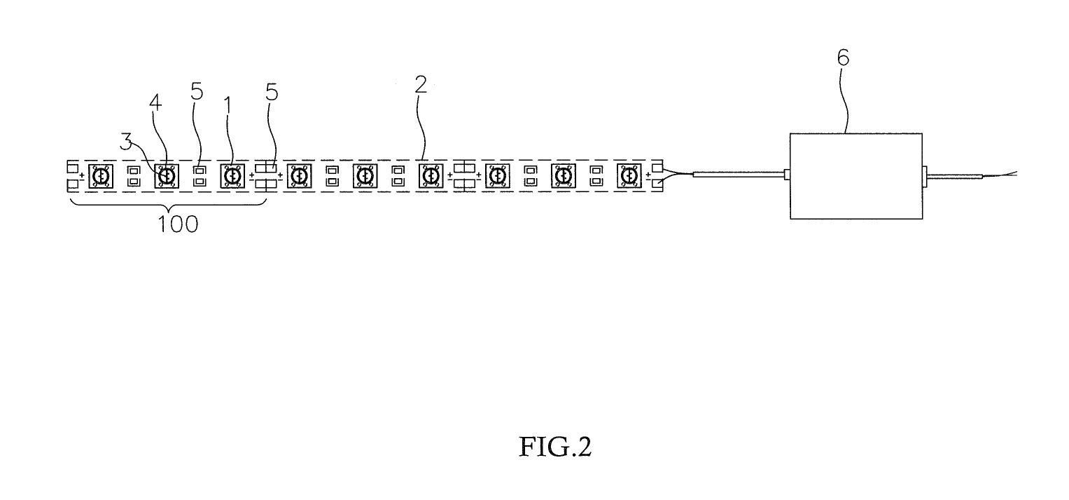

As shown in FIG. 2, the present invention discloses a flexible LED (Light-Emitting Diode) light bar, which comprises a flexible circuit board 1, a light cup 2, an LED chip 3, and a LED encapsulation material 4. The flexible circuit board 1 is of a predetermined design and is subjected to printing and etching to form wiring and thus subjected to an electrosilvering operation (electrosilvering being an operation for forming a coated layer of a printed circuit board (PCB), but the present invention being not limited to electrosilvering) to form a reflective layer. The light cup 2 is formed on the flexible circuit board 1 through injection molding. The LED chip 3 is encapsulated by applying the LED encapsulation material 4 (resin, fluorescent powder, and gold bonding wire) in the light cup 2 and bonded to the flexible circuit board 1 so that the LED chip 3 is in electrical connection with the flexible circuit board 1. FIG. 2 further shows electronic components 5 (such as resistors and ICs). The electronic components 5 are soldered to the flexible circuit board 1 so that the electronic components 5 are electrically connected to the flexible circuit board 1 to achieve various control functions. In the embodiment shown in FIG. 2, the flexible LED light bar comprises multiple sets of the flexible circuit board 1, the light cup 2, the LED chip 3, the LED encapsulation material 4, and the electronic components 5. And, every three sets of the flexible circuit board 1, the light cup 2, the LED chip 3, the LED encapsulation material 4, and the electronic components 5 constitute a unit light bar 100. According to a desired length, a multiplicity of the unit light bars 100 are jointed and electrically connected to form a flexible LED light bar of a predetermined length. The connected flexible LED light bar is then subject to application of waterproof silicon resin to meet requirements for water resistance.

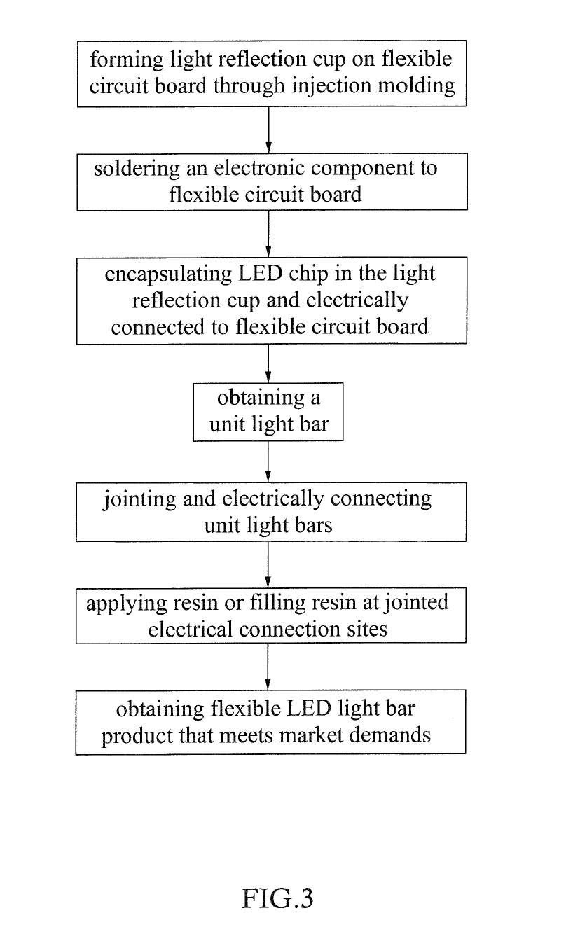

As shown in FIG. 3, the present invention discloses a manufacturing method of a flexible LED light bar, which comprises the following steps:
a first step of forming a flexible circuit board 1 by means of printing and etching;
a pre-second step of applying an electrosilvering operation (electrosilvering being an operation for forming a coated layer of a printed circuit board (PCB), but the present invention being not limited to electrosilvering) to form a reflective layer on the flexible circuit board 1;
a second step of forming a light cup 2 through injection molding on the flexible circuit board 1;
a pre-third step of using manufacturing facility to solder electronic component s5 (such as resistors and ICs) on the flexible circuit board 1 in such a way that the electronic components 5 are in electrical connection with the flexible circuit board 1;
a third step of using LED encapsulation facility (die bonding, wire bonding, and resin application machines) and an LED encapsulation material 4 to encapsulate the LED chip 3 in the light cup 2 and bonded to the flexible circuit board 1 and also to electrically connect the LED chip 3 to the flexible circuit board 1; and
a fourth steps of providing three LED light bars formed in the third step to serve as a unit light bar 100 and, according to a desired length, jointing and electrically connecting a predetermined number of the unit light bars 100 together to form a flexible LED light bar of a predetermined length and further using manufacturing facility to apply a waterproof silicon resin to the flexible LED light bar to meet requirements for water resistance.

According to the present invention, each unit light bar 100 may comprise a number of flexible circuit boards 1, a number of light cups 2, a number of LED chips 3, a number of LED encapsulation materials 4, and a number of electronic components 5 and the numbers are determined according to the capacity of the manufacturing facility used. For upgraded facility, the length of a product can be extended so that there is no need to joint, in an end-to-end manner, a number of short products.

The flexible LED light bar so manufactured according to the present invention, when put into operation, is connected with an external power source 6. When the flexible LED light bar is in operation, since the LED chip 3 is set in direct contact with the flexible circuit board 1, the heat generated by the LED chip 3 can be well transmitted out via the flexible circuit board 1 and the heat dissipative area is expanded, allowing for reduction of operation temperature of the LED chip, reduction of optic deterioration of the LED chip, increase of product reliability

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A flexible LED (Light-Emitting Diode) light bar, characterized by comprising a flexible circuit board, a light cup, an LED chip, and an LED encapsulation material, the light cup being formed on the flexible circuit board, the LED chip being encapsulated by the LED encapsulation material in the light cup and bonded to the flexible circuit board, the LED chip being in electrical connection with the flexible circuit board.

2. The flexible LED light bar according to claim 1, characterized in that the flexible LED light bar further comprises an electronic component, the electronic component being soldered to the flexible circuit board, the electronic component being in electrical connection with the flexible circuit board.

3. The flexible LED light bar according to claim 1, characterized in that the flexible LED light bar comprises multiple sets of the flexible circuit board, the light cup, the LED chip, and the LED encapsulation material, which are electrically connected to each other through series connection or parallel connection or a combination of series and parallel connections.

4. The flexible LED light bar according to claim 1, characterized in that the flexible circuit board comprises a circuit board formed through printing and etching.

5. The flexible LED light bar according to claim 1, characterized in that the flexible circuit board further comprises a reflective layer formed through electroplating, sputtering, or nano-spray coating.

6. A manufacturing method of a flexible LED (Light-Emitting Diode) light bar, characterized by comprising the following steps:
(1) providing a flexible circuit board;
(2) forming a light cup on the flexible circuit board; and
(3) using LED encapsulation facility and an LED encapsulation material to encapsulate the LED chip in the light cup and bonded to the flexible circuit board and establishing an electrical connection between the LED chip and the flexible circuit board so as to form an LED light bar.

7. The manufacturing method of the flexible LED light bar according to claim 6, characterized in that a pre-step is performed before step (3) and comprises using manufacturing facility to solder an electronic component to the flexible circuit board so that an electrical connection is established between the electronic component and the flexible circuit board.

8. The manufacturing method of the flexible LED light bar according to claim 6, characterized in that step (4) is performed after step (3) and comprises jointing a number of the LED light bars formed in step (3) to each other through series connection, parallel connection or a combination of series and parallel connection.

9. The manufacturing method of the flexible LED light bar according to claim 6, characterized in that a pre-step is formed before step (2) and comprising a reflective layer on the flexible circuit board through electroplating, sputtering, or nano-spray coating.

10. The manufacturing method of the flexible LED light bar according to claim 6, characterized in that the flexible circuit board comprises a circuit board that is formed through printing or etching.
